(19) United States
(12) Patent Application Publication
(10) Pub. No.: US 2024/0429153 A1
(43) Pub. Date: Dec. 26, 2024

(54) PACKAGE SUBSTRATE AND SEMICONDUCTOR PACKAGE INCLUDING THE SAME

(71) Applicant: Samsung Electronics Co., Ltd., Suwon-si (KR)

(72) Inventor: Myungsam Kang, Suwon-si (KR)

(21) Appl. No.: 18/665,082

(22) Filed: May 15, 2024

(30) Foreign Application Priority Data
Jun. 26, 2023 (KR) 10-2023-0082131

(51) Int. Cl. H01L 23/498; H01L 23/00; H01L 23/15; H01L 23/538; H01L 25/065; H01L 25/10

(52) U.S. Cl. CPC H01L 23/49838; H01L 23/15; H01L 23/49816; H01L 23/49822; H01L 23/538; H01L 24/16; H01L 25/0655; H01L 25/105; H01L 2224/16227; H01L 2225/1023; H01L 2225/1035; H01L 2225/1041; H01L 2225/1058; H01L 2924/15174

(57) ABSTRACT

A package substrate including a glass substrate having a first surface and a second surface opposite thereto, and including a plurality of through holes extending from the second surface to the first surface of the glass substrate, a plurality of wiring patterns each including a through electrode positioned in the plurality of through holes and a via pad extending from the through electrode to cover a portion of the second surface of the glass substrate, a seed layer arranged between the glass substrate and the plurality of wiring patterns, and including a first surface coplanar with the first surface of the glass substrate, wherein the through electrode of each of the plurality of wiring patterns includes a first surface coplanar with the first surface of the glass substrate.

### CROSS-REFERENCE TO RELATED APPLICATION

This application is based on and claims priority under 35 U.S.C. § 119 to Korean Patent Application No. 10-2023-0082131, filed on Jun. 26, 2023 in the Korean Intellectual Property office, the disclosure of which is incorporated by reference herein in its entirety.

### BACKGROUND

Aspects of the inventive concept relate to a package substrate and a semiconductor package including the package substrate, and more particularly, to a package substrate including a glass substrate and a semiconductor package including the package substrate.

Due to advancements in the electronic industry, demand for high functionality, high speed, and miniaturization of electronic components has increased. According to this trend, there is an increasing need for miniaturization and multi-functionalization of semiconductor chips used in electronic components. In addition, in the field of semiconductor packages, the size thereof is miniaturized based on small semiconductor chips. In addition, due to demand for improved performance and form factor reduction of the semiconductor packages, the semiconductor package structure is moving toward a multi-chip integrated structure. In this case, the multi-chip integration may mean integration of chips manufactured in different processes in a single semiconductor package together.

### SUMMARY

Aspects of the inventive concept provide a package substrate having improved design degree of freedom and a semiconductor package including the package substrate.

Aspects of the inventive concept provide a package substrate having improved characteristics of signal integrity (SI) and power integrity (PI) characteristics and a semiconductor package including the package substrate.

In addition, the issues to be solved in accordance with aspects of the inventive concept are not limited to those mentioned above, and other issues may be clearly understood by those of ordinary skill in the art from the following descriptions.

According to an aspect of the inventive concept, there is provided a package substrate including a glass substrate including a first surface and a second surface opposite thereto, and including a plurality of through holes extending from the second surface to the first surface of the glass substrate, a plurality of wiring patterns each including a through electrode positioned in the plurality of through holes and a via pad extending from the through electrode to cover a portion of the second surface of the glass substrate, a seed layer arranged between the glass substrate and the plurality of wiring patterns, and including a first surface coplanar with the first surface of the glass substrate, wherein the through electrode of each of the plurality of wiring patterns includes a first surface coplanar with the first surface of the glass substrate.

According to another aspect of the inventive concept, there is provided a semiconductor package including a package substrate, and at least one semiconductor chip arranged on the package substrate, wherein the package substrate includes a glass substrate including a first surface and a second surface opposite thereto, and including a plurality of through holes extending from the second surface to the first surface of the glass substrate, a plurality of wiring patterns respectively positioned in the plurality of through holes, the plurality of wiring patterns each including a through electrode including a first surface coplanar with the first surface of the glass substrate and a via pad extending from the through electrode to cover a portion of the second surface of the glass substrate, a seed layer arranged between the glass substrate and the plurality of wiring patterns, and including a first surface coplanar with the first surface of the glass substrate, and a first redistribution structure arranged on at least one surface of the first surface and the second surface of the glass substrate, wherein the through electrode of each of the plurality of wiring patterns includes a first surface coplanar with the first surface of the glass substrate.

According to another aspect of the inventive concept, there is provided a semiconductor package including a package substrate, at least one semiconductor chip arranged on the package substrate, and an external connection terminal arranged on the package substrate, and disposed apart from the at least one semiconductor chip with the package substrate therebetween, wherein the package substrate includes a glass substrate including a first surface and a second surface opposite thereto, and including a plurality of through holes including a horizontal width decreasing and extending from the second surface to the first surface of the glass substrate, a plurality of wiring patterns respectively positioned in the plurality of through holes, the plurality of wiring patterns each including a through electrode including a first surface coplanar with the first surface of the glass substrate and a via pad extending from the through electrode to cover a portion of the second surface of the glass substrate, a seed layer arranged between the glass substrate and the wiring patterns, and including a first surface coplanar with the first surface of the glass substrate, a first redistribution structure including a plurality of redistribution vias, a redistribution insulating layer, and a plurality of redistribution line patterns, and arranged on the first surface of the glass substrate, and a second redistribution structure arranged on the second surface of the glass substrate, and including a plurality of redistribution vias, a redistribution insulating layer, and a plurality of redistribution line patterns, wherein the plurality of redistribution vias of the first redistribution structure have a horizontal width less than a horizontal width of each of the plurality of through holes, and contact the first surface of the through electrode of the plurality of wiring patterns.

### BRIEF DESCRIPTION OF THE DRAWINGS

Embodiments will be more clearly understood from the following detailed description taken in conjunction with the accompanying drawings in which:

FIG. 1 is a schematic cross-sectional view of a package substrate according to an embodiment;

FIG. 2 is an enlarged cross-sectional view of region II in FIG. 1;

FIG. 3 is a schematic cross-sectional view of a package substrate according to an embodiment;

FIG. 4 is a schematic cross-sectional view of a package substrate according to an embodiment;

FIG. 5 is a schematic cross-sectional view of a package substrate according to an embodiment;

FIG. 6 is a schematic cross-sectional view of a semiconductor package according to an embodiment;

FIG. 7 is a schematic cross-sectional view of a semiconductor package according to an embodiment;

FIG. 8 is a schematic cross-sectional view of a semiconductor package according to an embodiment;

FIG. 9 is a schematic cross-sectional view of a semiconductor package according to an embodiment; and

FIGS. 10 through 15 are cross-sectional views illustrating a manufacturing method of a semiconductor package according to a process sequence, according to embodiments.

### DETAILED DESCRIPTION OF THE EMBODIMENTS

Because various changes can be applied to the embodiments and accordingly, the embodiments can have various types, some embodiments are illustrated in the drawings and detailed descriptions thereof are provided. However, the various changes are not intended to limit the embodiments to particular disclosure forms.

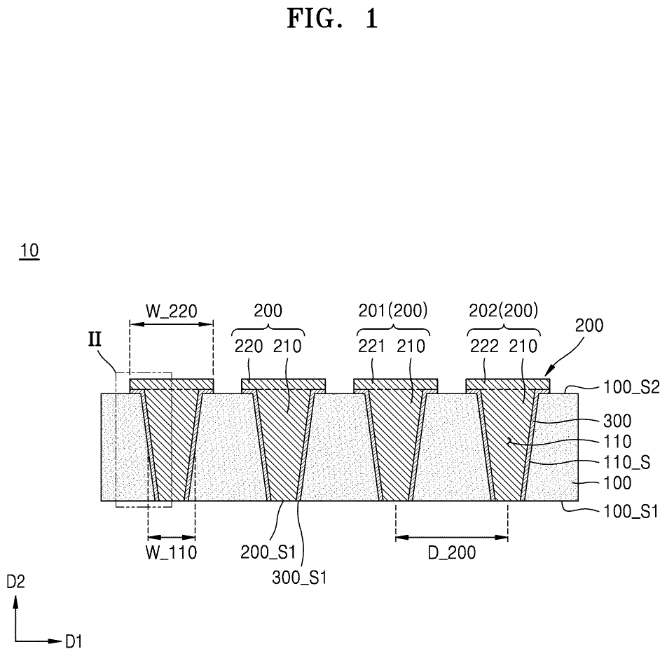

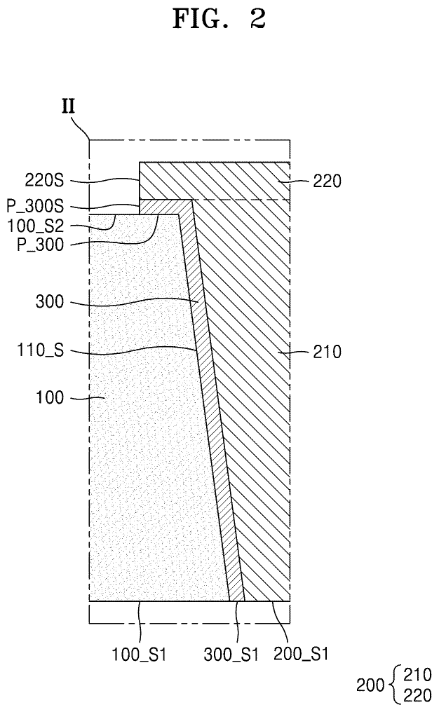

FIG. 1 is a schematic cross-sectional view of a package substrate 10 according to an embodiment. FIG. 2 is an enlarged cross-sectional view of region II in FIG. 1.

Referring to FIGS. 1 and 2, the package substrate 10 may include a glass substrate 100, a plurality of wiring patterns 200, and a seed layer 300.

The glass substrate 100 of the package substrate 10 may include a first surface 100_S1 and a second surface 100_S2 opposite thereto. Hereinafter, unless specifically defined, a direction in parallel with the first surface 100_S1 of the glass substrate 100 may be defined as a horizontal direction D1, and a direction perpendicular to the first surface 100_S1 may be defined as a vertical direction D2.

In some embodiments, the glass substrate 100 may include or may be formed of an inorganic material, glass, or ceramic. In general, glass may have good characteristics in terms of smoothness, thermal expansion coefficient, surface hardness, etc. For example, glass may have good smoothness and may be easily made wide and flat. In addition, glass may have a low thermal expansion coefficient of 9.0*10⁻⁶° C., and a high hardness of about 6 H to about 7 H. In some embodiments, the glass used in the glass substrate 100 may, as a reinforced glass having increased tensile strength, may have high rigidity.

The glass substrate 100 may have a rectangular flat plate (e.g., planar) shape. The glass substrate 100 may have a thickness (i.e., in the vertical direction D2) of about 50 μm to about 1500 μm. However, the thickness of the glass substrate 100 is not limited thereto.

The glass substrate 100 may include a plurality of through holes 110 extending from the second surface 100_S2 to the first surface 100_S1. Each of a plurality of through holes 110 may have a narrower horizontal width W_110 (i.e., in the horizontal direction D1) toward the first surface 100_S1 of the glass substrate 100. Each of the plurality of through holes 110 may have a horizontal width W_110 on the first surface 100_S1 of the glass substrate 100 that is less than the horizontal width W_110 on the second surface 100_S2 of the glass substrate 100.

In some embodiments, the sidewall 110_S of the glass substrate 100 defining the plurality of through holes 110 may have an inclination. For example, the sidewall 110_S of the glass substrate 100 defining the plurality of through holes 110 may be inclined at an acute angle with respect to the first surface 100_S1 of the glass substrate 100.

Each of the plurality of wiring patterns 200 of the package substrate 10 may include a through electrode 210 and a via pad 220. For reference, because the plurality of wiring patterns 200 have a structure penetrating the glass substrate 100, the plurality of wiring patterns 200 may be referred to as a through glass via (TGV).

The through electrode 210 and the via pad 220 may be formed together. For example, the through electrode 210 and the via pad 220 may be formed together by using an electro-plating process using the seed layer 300. Although the through electrode 210 and the via pad 220 are distinguished by a dashed line in FIGS. 1 and 2, they may actually have the form of one-body integrally combined. For example, in some embodiments, the through electrode 210 and the via pad 220 may not be distinguished as individual components, but may be treated as one component.

In some embodiments, the plurality of wiring patterns 200 may be arranged apart from each other in the horizontal direction D1. In the plurality of wiring patterns 200, a separation distance D_200 between vertical axes of two adjacent wiring patterns 200 may be about 100 μm to about 200 μm. The separation distance D_200 of the vertical axes of the two wiring patterns 200 may vary according to the thickness of the glass substrate 100.

In some embodiments, the plurality of wiring patterns 200 may include first wiring patterns 201 and second wiring patterns 202. Although not illustrated, a via pad 221 of the first wiring pattern 201 may extend along the second surface 100_S2 of the glass substrate 100, and may be connected to the via pad 222 of the second wiring pattern 202. For example, the via pad 221 of the first wiring pattern 201 and the via pad 222 of the second wiring pattern 202 may be integrally combined. The via pad 221 of the first wiring pattern 201 and the via pad 222 of the second wiring pattern 202 may be formed as one-body, depending on the shape of the mask.

In some embodiments, the plurality of wiring patterns 200 may include a metal, a conductive metal oxide, a conductive metal nitride, etc. For example, the plurality of wiring patterns 200 may include or may be formed of copper (Cu), tungsten (W), aluminum (Al), nickel (Ni), cobalt (Co), titanium (Ti), titanium nitride (TiN), etc. The plurality of wiring patterns 200 may be formed by, for example, using an electroplating process. However, the embodiment is not limited thereto, the plurality of wiring patterns 200 may be formed by using other processes, such as electroless plating, deposition, and sputtering.

The through electrode 210 of each of the plurality of wiring patterns 200 may be positioned in each of the plurality of through holes 110. A first surface 200_S1 of the through electrode 210 may be coplanar with the first surface 100_S1 of the glass substrate 100. For example, the first surface 200_S1 of the through electrode 210 may not be covered by the seed layer 300.

In some embodiments, the through electrode 210 may have, for example, a cylindrical shape penetrating the glass substrate 100. However, the shape of the through electrode 210 is not limited thereto. For example, according to some embodiments, the through electrode 210 may also have an elliptical pillar or polygonal pillar shape.

A horizontal width of the through electrode 210 may correspond to the horizontal width W_110 of each of the plurality of through holes 110. For example, the through electrode 210 may have a shape in which the horizontal width thereof decreases toward the first surface 100_S1 of the glass substrate 100, like the plurality of through holes 110. For example, the horizontal width of the through electrode 210 may be greater on the second surface 100_S2 of the glass substrate 100 than that on the first surface 100_S1 of the glass substrate 100.

The via pad 220 of each of the plurality of wiring patterns 200 may extend from the through electrode 210 to cover a portion of the second surface 100_S2 of the glass substrate 100. For example, because a horizontal width of the via pad 220 is greater than that of each of the plurality of through holes 110, the via pad 220 may cover a portion of the second surface 100_S2 of the glass substrate 100. For example, although the horizontal width of the through electrode 210 increases even toward the second surface 100_S2 of the glass substrate 100, the horizontal width of the via pad 220 may be greater than the maximum horizontal width of the through electrode 210.

In some embodiments, the via pad 220 may have a circular or rectangular flat plate (e.g., planar) shape. Accordingly, a cross-section of the via pad 220 may have, for example, a rectangular shape elongated in the horizontal direction D1.

The seed layer 300 of the package substrate 10 may be arranged between the glass substrate 100 and each of the plurality of wiring patterns 200. The seed layer 300 may comprise a first portion (e.g., protrusion portion) and a second portion. The protrusion portion P_300 of the seed layer 300 may located between the via pad 220 and the second surface 100_S2 of the glass substrate 100. The second portion of the seed layer 300 extends from the protrusion portion P_300 to 100_S1 of the glass substrate 100 along the sidewall 110_S of the glass substrate 100.

For example, the seed layer 300 may extend along the protrusion portion P_300 between the via pad 220 and the second surface 100_S2 of the glass substrate 100, and may extend along the sidewall 110_S of the glass substrate 100 defining each of the plurality of through holes 110 from the protrusion portion P_300 and the first surface 100_S1 of the glass substrate 100. In some embodiments, the seed layer 300 may conformally extend along a portion of the second surface 100_S2 of the glass substrate 100 and the sidewall 110_S of the glass substrate 100, which defines each of the plurality of through holes 110.

The seed layer 300 may include a first surface 300_S1 coplanar with the first surface 100_S1 of the glass substrate 100. For example, in the process of removing portions of the glass substrate 100, the through electrode 210, and the seed layer 300, the first surface 100_S1 of the glass substrate 100, the first surface 200_S1 of the through electrode 210, and the first surface 300_S1 of the seed layer 300 may be coplanar with each other.

In some embodiments, a side surface P_300S of the protrusion portion P_300 may be coplanar with a side surface 220S of each via pad 220 of the plurality of wiring patterns 200. In the process of forming the via pad 220, a portion of the via pad 220 and a portion of the protrusion portion P_300 of the seed layer 300 may be removed in the same shape, so that the side surface 220S of the via pad 220 may be coplanar with the side surface P_300S of the protrusion portion P_300 of the seed layer 300.

In some embodiments, the seed layer 300 may include or may be for the of a metal, such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Rc), beryllium (Be), gallium (Ga), and ruthenium (Ru), or an alloy thereof, but is not limited thereto.

In some embodiments, the seed layer 300 may be formed by using a deposition process, such as atomic layer deposition (ALD), chemical vapor deposition (CVD), and physical vapor deposition (PVD). When the wiring pattern 200 is electroplated on the glass substrate 100, the seed layer 300 may help the wiring pattern 200, especially the through electrode 210 of the wiring pattern 200, completely fill the inside of the plurality of through holes 110 of the glass substrate 100.

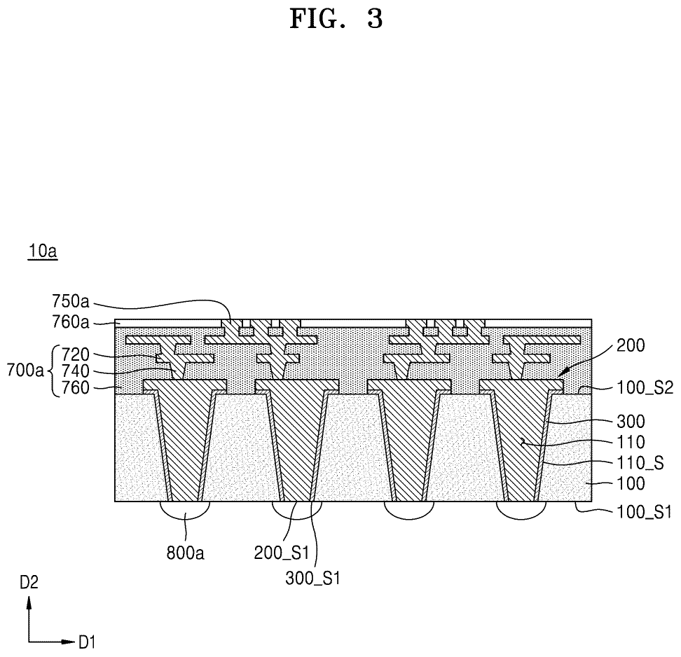

FIG. 3 is a schematic cross-sectional view of a package substrate 10a according to an embodiment.

Referring to FIG. 3, the package substrate 10a may include the glass substrate 100, the plurality of wiring patterns 200, the seed layer 300, and a second redistribution structure 700a.

Hereinafter, duplicate descriptions of the package substrate 10a of FIG. 3 and the package substrate 10 of FIG. 1 are omitted, and differences thereof are given. The package substrate 10a of FIG. 3 may be different from the package substrate 10 of FIG. 1 with respect to the second redistribution structure 700a, and all, except for this difference, may be substantially the same.

The second redistribution structure 700a of the package substrate 10a may be on the second surface 100_S2 of the glass substrate 100. The second redistribution structure 700a may include a plurality of redistribution vias 740, a plurality of redistribution line patterns 720, and a redistribution insulating layer 760.

Although the redistribution insulating layer 760 is illustrated as one layer in FIG. 3, the redistribution insulating layer 760 may include a plurality of layers. When the redistribution insulating layer 760 includes a plurality of layers, the plurality of redistribution line patterns 720 may be arranged on at least one of an upper surface and a lower surface of each layer of the redistribution insulating layer 760.

The plurality of redistribution vias 740 may penetrate the redistribution insulating layer 760, and may contact and be connected to some of the plurality of redistribution line patterns 720. In some embodiments, at least some of the plurality of redistribution line patterns 720 may be formed in one body together with some of the plurality of redistribution vias 740. For example, a redistribution line pattern 720 and the redistribution via 740 contacting an upper surface of the redistribution line pattern 720 may be formed as one body.

The redistribution insulating layer 760 may surround the plurality of redistribution line patterns 720 and the plurality of redistribution vias 740. In some embodiments, the redistribution insulating layer 760 may surround the side surface 220S of the via pad 220 of the plurality of wiring patterns 200, the side surface (P_300 in FIG. 2) of the protrusion portion (P_300 in FIG. 2) of the seed layer 300, and a portion of the second surface 100_S2 of the glass substrate 100.

The plurality of redistribution line patterns 720 and the plurality of redistribution vias 740 may be electrically connected to the via pad 220. In some embodiments, at least some of the plurality of redistribution vias 740 may be in contact with the via pad 220 of each of the plurality of wiring patterns 200. It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting,” “in contact with,” or “contact” another element, there are no intervening elements present at the point of contact.

In some embodiments, each of the plurality of redistribution vias 740 may have a tapered shape, in which a horizontal width thereof decreases as the redistribution vias 740 extend along the vertical direction D2. For example, the plurality of redistribution vias 740 may have a greater horizontal width away from the glass substrate 100. However, the plurality of redistribution vias 740 are not limited thereto, and may have a narrower horizontal width toward the glass substrate 100.

Among the plurality of redistribution line patterns 720, the redistribution line pattern 720 arranged on a surface exposed to the outside of the second redistribution structure 700a may be referred to as a redistribution pad 750a. A semiconductor chip may be mounted on the redistribution pad 750a. The redistribution pad 750a may be surrounded by a passivation layer 760a on the redistribution insulating layer 760.

The redistribution line pattern 720 and the redistribution via 740 may include or may be formed of, for example, a metal, such as Cu, Al, W, Ti, Ta, In, Mo, Mn, Co, Sn, Ni, Mg, Re, Be, Ga, and Ru, or an alloy thereof, but are not limited thereto. The redistribution insulating layer 760 may be formed from, for example, photo imageable dielectric (PID) or photosensitive polyimide (PSPI).

A plurality of external connection terminals 800a of the package substrate 10a may be on the first surface 100_S1 of the glass substrate 100. The plurality of external connection terminals 800a may be disposed apart from the second redistribution structure 700a with the glass substrate 100 therebetween. The plurality of external connection terminals 800a may cover a portion of the first surface 100_S1 of the glass substrate 100, the first surface 200_S1 of the through electrode 210 of the plurality of wiring patterns 200, and the first surface 300_S1 of the seed layer 300.

The plurality of external connection terminals 800a may be configured to electrically and physically connect the package substrate 10a to the external device, and may be configured to transmit an electrical signal between the package substrate 10a and the external device. The plurality of external connection terminals 800a may be formed from solder balls or solder bumps.

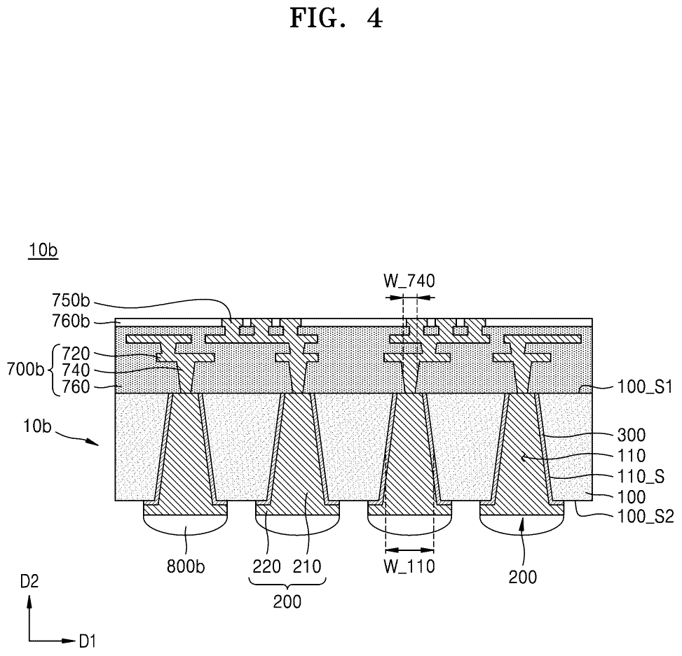

FIG. 4 is a schematic cross-sectional view of a package substrate 10b according to an embodiment.

Referring to FIG. 4, the package substrate 10b may include the glass substrate 100, the plurality of wiring patterns 200, the seed layer 300, and a first redistribution structure 700b.

Hereinafter, duplicate descriptions of the package substrate 10b of FIG. 4 and the package substrate 10a of FIG. 3 are omitted, and differences thereof are given. The package substrate 10b of FIG. 4 may be different from the package substrate 10a of FIG. 3 with respect to the first redistribution structure 700b and a plurality of external connection terminals 800b, and all, except for these differences, may be substantially the same.

The first redistribution structure 700b of the package substrate 10b may be on the first surface 100_S1 of the glass substrate 100. The first redistribution structure 700b may include the plurality of redistribution vias 740, the plurality of redistribution line patterns 720, and the redistribution insulating layer 760.

Some of the plurality of redistribution vias 740 may be in contact with the through electrode 210 of the plurality of wiring patterns 200. In some embodiments, some of the plurality of redistribution vias 740 may be in contact with the first surface 200_S1 of the through electrode 210.

A horizontal width W_740 of some of the plurality of redistribution vias 740 may be less than the horizontal width W_110 of each of the plurality of through holes 110 of the glass substrate 100. The horizontal width W_740 of the redistribution via 740 in contact with the first surface 200_S1 of the through electrode 210 among the plurality of redistribution vias 740 may be less than the horizontal width W_110 of each of the plurality of through holes 110.

In some embodiments, when the horizontal width W_110 of each of the plurality of through holes 110 decreases toward the first surface 100_S1 of the glass substrate 100, the horizontal width W_740 of some redistribution vias 740 among the plurality of redistribution vias 740 may be less than a minimum horizontal width of the horizontal width W_110 of each of the plurality of through holes 110.

The redistribution insulating layer 760 surrounding the plurality of redistribution vias 740 and the plurality of redistribution line patterns 720 may cover a portion of the first surface 200_S1 of the through electrode 210 of each of the plurality of wiring patterns 200. A region of the first surface 200_S1 of the through electrode 210, which does not contact the redistribution via 740, may be covered by the redistribution insulating layer 760. The redistribution insulating layer 760 may cover a portion of the first surface 200_S1 of the through electrode 210, the first surface 100_S1 of the glass substrate 100, and the first surface 300_S1 of the seed layer 300.

The redistribution line pattern 720 arranged on a surface exposed to the outside of the first redistribution structure 700b among the plurality of redistribution line patterns 720 may be referred to as a redistribution pad 750b. A semiconductor chip may be mounted in the redistribution pad 750b. The redistribution pad 750b may be surrounded by a passivation layer 760b on the redistribution insulating layer 760.

Each of the plurality of external connection terminals 800b of package substrates 10b may be on the via pad 220 of each of the plurality of wiring patterns 200. For example, the plurality of external connection terminals 800b may be disposed apart from the second surface 100_S2 of the glass substrate 100 in the vertical direction D2 with the via pad 220 therebetween. The plurality of external connection terminals 800b may be configured to transmit an electrical signal between the package substrate 10b and an external device. The plurality of external connection terminals 800b may be formed from solder balls or solder bumps.

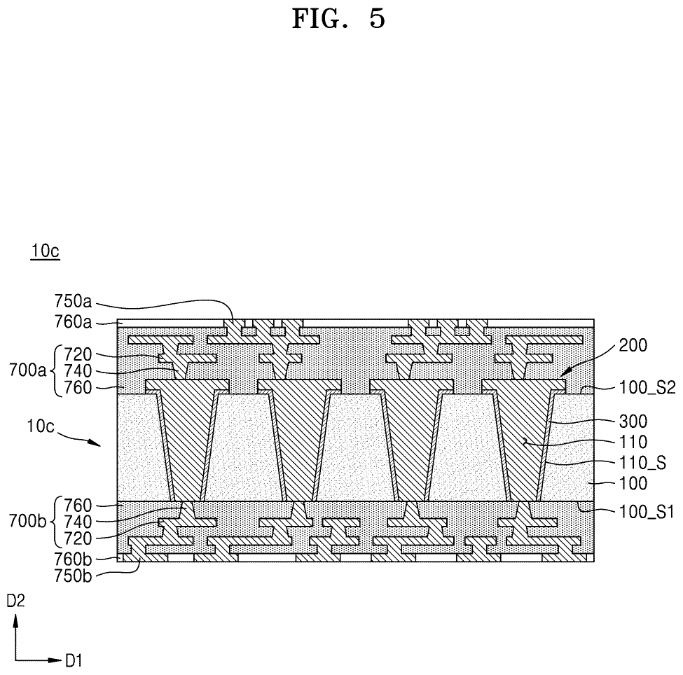

FIG. 5 is a schematic cross-sectional view of a package substrate 10c according to an embodiment.

Referring to FIG. 5, the package substrate 10c may include the glass substrate 100, the plurality of wiring patterns 200, the seed layer 300, and the second redistribution structure 700a.

Hereinafter, duplicate descriptions of the package substrate 10c of FIG. 5 and the package substrate 10 of FIG. 1 are omitted, and differences thereof are given. The package substrate 10c of FIG. 5 may be different from the package substrate 10 of FIG. 1 with respect to the first redistribution structure 700b and the second redistribution structure 700a, and all, except for these differences, may be substantially the same.

The first redistribution structure 700b of the package substrate 10c may be on the first surface 100_S1 of the glass substrate 100. The second redistribution structure 700a of the package substrate 10c may be on the second surface 100_S2 of the glass substrate 100. The first redistribution structure 700b may be electrically connected to the second redistribution structure 700a via the plurality of wiring patterns 200 of the glass substrate 100.

Each of the first redistribution structure 700b and the second redistribution structure 700a may include the plurality of redistribution vias 740, the plurality of redistribution line patterns 720, and the redistribution insulating layer 760. The first redistribution structure 700b may be substantially the same as the first redistribution structure 700b in FIG. 4. The second redistribution structure 700a may be substantially the same as the second redistribution structure 700a in FIG. 3.

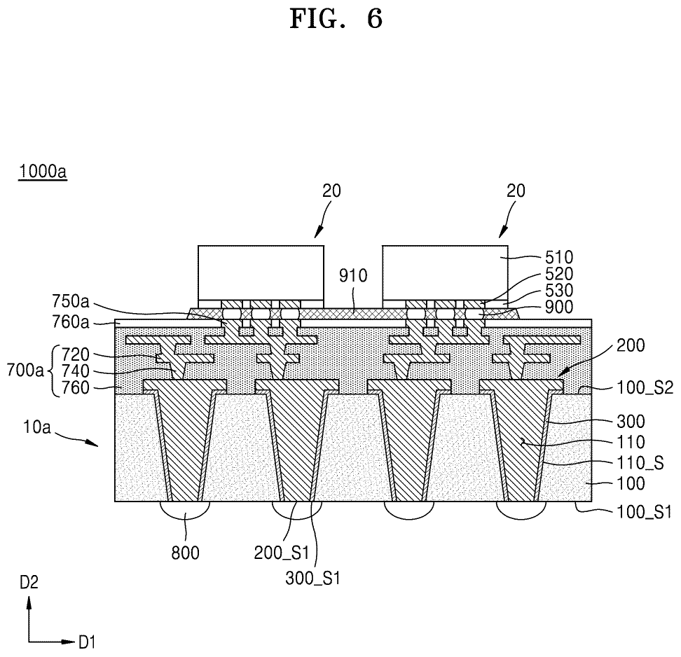

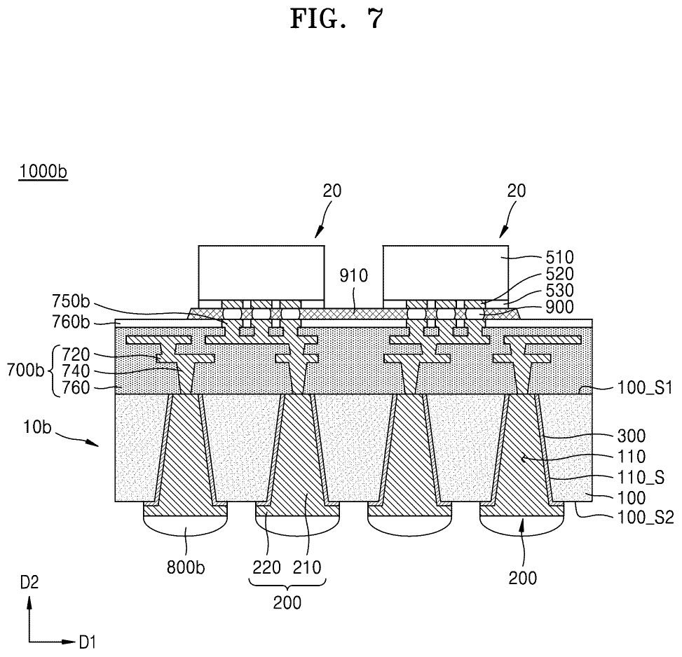

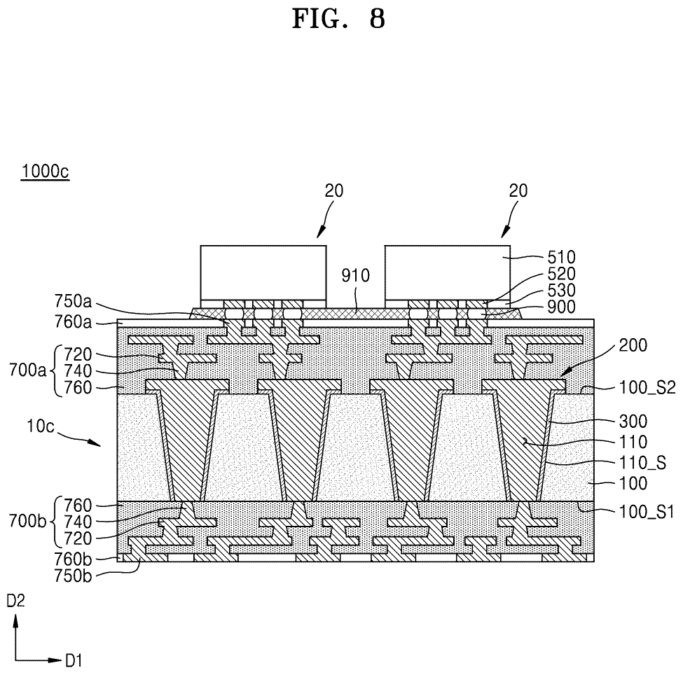

FIG. 6 is a schematic cross-sectional view of a semiconductor package 1000a according to an embodiment. FIG. 7 is a schematic cross-sectional view of a semiconductor package 1000b according to an embodiment. FIG. 8 is a schematic cross-sectional view of a semiconductor package 1000c according to an embodiment.

Referring to FIGS. 6 through 8, the semiconductor packages 1000a, 1000b, and 1000c may include the package substrates 10a, 10b, and 10c, respectively, and at least one semiconductor chip 20. In FIGS. 6 through 8, there may be differences in respect of the package substrates 10a, 10b, and 10c, and the remaining configurations, except for the differences, may be substantially the same.

The semiconductor packages 1000a, 1000b, and 1000c of FIGS. 6 through 8 may represent semiconductor packages including the package substrates 10a, 10b, and 10c of FIGS. 3 through 5, respectively. The semiconductor package 1000a of FIG. 6 may include the package substrate 10a of FIG. 3. The semiconductor package 1000b of FIG. 7 may include the package substrate 10b of FIG. 4. The semiconductor package 1000c of FIG. 8 may include the package substrate 10c of FIG. 5. Descriptions of the package substrates 10a, 10b, and 10c are duplicative of those described above, and are omitted.

At least one semiconductor chip 20 may include a semiconductor substrate 510 including an active surface and an inactive surface opposite to each other, a plurality of chip pads 520 arranged on the active surface of the semiconductor chip 20, and a passivation layer 530 surrounding the plurality of chip pads 520.

The semiconductor chip 20 may be arranged on the package substrates 10a, 10b, and 10c. The semiconductor chip 20 may be arranged on the redistribution pad 750a of the first redistribution structure 700a or the redistribution pad 750b of the second redistribution structure 700b of the package substrates 10a, 10b, and 10c. In FIG. 8, it is illustrated that the semiconductor chip 20 is arranged on the second redistribution structure 700a, but the embodiment is not limited thereto, and the semiconductor chip 20 may be arranged on the first redistribution structure 700b.

In an example embodiment, the semiconductor chip 20 may have a face down arrangement, in which the active surface thereof faces the package substrates 10a, 10b, and 10c, and may be arranged on the package substrates 10a, 10b, and 10c. In this case, a plurality of chip connection terminals 900 may be arranged between the plurality of chip pads 520 of the semiconductor chip 20 and some of the redistribution pads 750a and 750b of the package substrate 10a, 10b, and 10c, respectively. The plurality of chip connection terminals 900 may include, for example, solder balls or bumps, but are not limited thereto. The semiconductor chip 20 may be electrically connected to the package substrates 10a, 10b, and 10c via the plurality of chip connection terminals 900. In addition, the semiconductor chip 20 may be combined with the package substrates 10a, 10b, and 10c by using a hybrid bonding process.

In an embodiment, an underfill layer 910 may be arranged between the passivation layer 530 of the semiconductor chip 20 and passivation layers 760a and 760b of the package substrates 10a, 10b, and 10c. The underfill layer 910 may surround the plurality of chip connection terminals 900. The underfill layer 910 may include, for example, epoxy resin formed by using a capillary underfill method.

In FIGS. 6 through 8, two semiconductor chips 20 are illustrated as arranged on the package substrates 10a, 10b, and 10c, but the embodiment is not limited thereto, and the number of the semiconductor chips may be one or three or more. In addition, although it is illustrated that two semiconductor chips 20 are arranged in parallel with each other in the horizontal direction D1 on the package substrates 10a, 10b, and 10c, the embodiment is not limited thereto, and at least two semiconductor chips 20 may be stacked in the vertical direction D2.

In an example embodiment, the semiconductor chip 20 may include a central processing unit (CPU) chip, a graphics processing unit (GPU) chip, or an application processor (AP) chip.

According to another example embodiment, the semiconductor chip 20 may include, for example, a memory semiconductor chip. The memory semiconductor chip may include, for example, a non-volatile memory semiconductor chip, such as flash memory, phase change random access memory (RAM) (PRAM), magnetic RAM (MRAM), ferroelectric RAM (FeRAM), or resistive RAM (RRAM). The flash memory may include, for example, an NAND flash memory, or a V-NAND flash memory. In an embodiment, the semiconductor chip 20 may include a volatile memory semiconductor chip, such as dynamic RAM (DRAM) and static RAM (SRAM).

The semiconductor substrate 510 may include, for example, a Group IV semiconductor, such as silicon (Si) and germanium (Ge), a Group IV-IV compound semiconductor, such as silicon-germanium (SiGe) and silicon carbide (SiC), or a Group III-V semiconductor, such as gallium arsenide (GaAs), indium arsenide (InAs), and indium phosphide (InP). The semiconductor substrate 510 may include a conductive region, for example, a well doped with impurities. The semiconductor substrate 510 may have various device isolation structures such as a shallow trench isolation (STI) structure.

A semiconductor device including a plurality of individual devices of various types may be formed on the active surface of the semiconductor substrate 510. The plurality of individual devices may include various microelectronic devices, for example, a metal-oxide-semiconductor field effect transistor (MOSFET) such as a complementary metal-oxide-semiconductor (CMOS) transistor, an image sensor, such as system large scale integration (LSI) and a CMOS imaging sensor (CIS), a micro electro-mechanical system (MEMS), an active element, a passive element, etc.

The plurality of individual devices may be electrically connected to the conductive region of the semiconductor substrate 510. A semiconductor device may further include a conductive wiring or a conductive plug, which electrically connects at least two of the plurality of individual elements to each other, or connects the plurality of individual devices to the conductive region of the semiconductor substrate 510. In addition, each of the plurality of individual devices may be electrically isolated from another adjacent individual devices by an insulating layer.

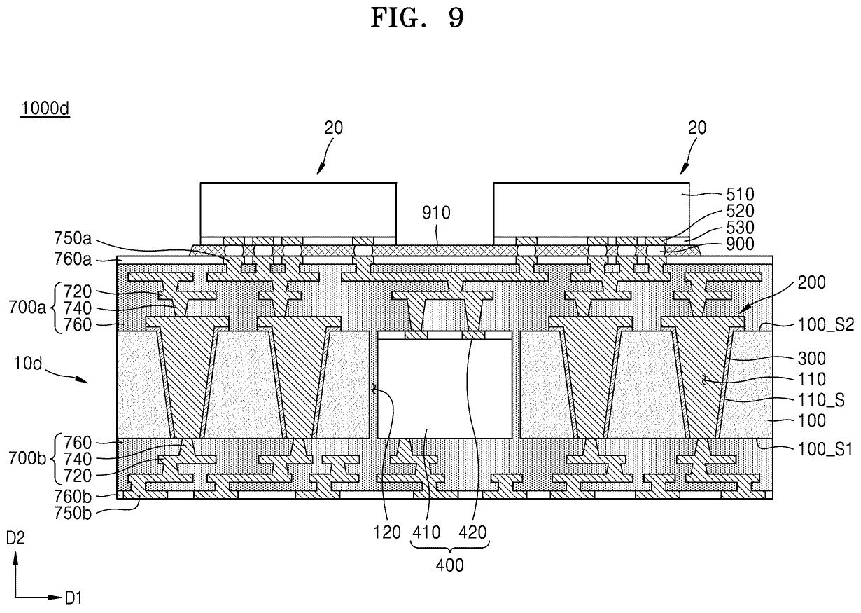

FIG. 9 is a schematic cross-sectional view of a semiconductor package 1000d according to an embodiment.

Referring to FIG. 9, the semiconductor package 1000d may include a package substrate 10d and at least one semiconductor chip 20. The semiconductor package 1000d of FIG. 9 may be different from the semiconductor package 1000c of FIG. 8 with respect to a buried semiconductor chip 400, and the remaining configuration thereof, except for the buried semiconductor chip 400, may be substantially the same. Hereinafter, duplicate descriptions of the semiconductor package 1000d given with reference to FIG. 9 and the semiconductor package 1000c given with reference to FIG. 8 are omitted, and differences thereof are mainly described.

The package substrate 10d of the semiconductor package 1000d may include the glass substrate 100, the plurality of wiring patterns 200, the seed layer 300, and the second redistribution structure 700a. In some embodiments, the semiconductor package 1000d may include at least one of the first redistribution structure 700b and the second redistribution structure 700a. However, hereinafter, a case in which both the first redistribution structure 700b and the second redistribution structure 700a are included is mainly described.

The glass substrate 100 of the package substrate 10d may include the plurality of through holes 110 and a cavity 120. The plurality of through holes 110 and the cavity 120 may extend from the first surface 100_S1 of the glass substrate 100 to the second surface 100_S2. The horizontal width W_110 of each of the plurality of through holes 110 may decrease along the vertical direction D2. For example, as illustrated in FIG. 9, the horizontal width W_110 of each of the plurality of through holes 110 may decrease as the through holes 110 extend toward the first surface 100_S1 of the glass substrate 100 along the vertical direction D2. The plurality of through holes 110 may include the plurality of through holes 110 described above.

The cavity 120 of the glass substrate 100 may have a structure penetrating the glass substrate 100. A horizontal cross-sectional area of the cavity 120 may have a rectangular shape, but is not limited thereto. For example, the horizontal cross-section of the cavity 120 may have a polygonal shape other than a circular shape, an elliptical shape, or a rectangular shape, in response to shapes of components arranged in the cavity 120.

The plurality of wiring patterns 200 and the seed layer 300 of the semiconductor package 1000d may be substantially the same as the plurality of wiring patterns 200 and the seed layer 300 in FIG. 1.

The first redistribution structure 700b and the second redistribution structure 700a of the semiconductor package 1000d may be arranged on the first surface 100_S1 and the second surface 100_S2 of the glass substrate 100, respectively. At least one of the first redistribution structure 700b and the second redistribution structure 700a may be electrically connected to the buried semiconductor chip 400 to be described below. Except for that, the first redistribution structure 700b and the second redistribution structure 700a may be substantially the same as the first redistribution structure 700b and the second redistribution structure 700a in FIG. 5.

The buried semiconductor chip 400 may be arranged inside the cavity 120 of the glass substrate 100. The buried semiconductor chip 400 may include a semiconductor substrate 410 and a plurality of chip pads 420. In some embodiments, the buried semiconductor chip 400 may further include a through electrode (not illustrated).

The glass substrate 100 including the buried semiconductor chip 400 may have a structure in which the glass substrate 100 is arranged in the first redistribution structure 700b and the second redistribution structure 700a. For example, the redistribution insulating layer 760 of each of the first redistribution structure 700b and the second redistribution structure 700a may cover the first and second surfaces 100_S1 and 100_S2 of the glass substrate 100, and may also cover the upper and lower surfaces of the buried semiconductor chip 400.

The redistribution line pattern 720 or the redistribution via 740 of the first redistribution structure 700b may be arranged on the plurality of chip pads 420 of the buried semiconductor chip 400. For example, the buried semiconductor chip 400 may be electrically connected to at least one semiconductor chip 20 arranged on the second redistribution structure 700a, via the second redistribution structure 700a. However, the embodiment is not limited thereto, and, although not illustrated, the redistribution line pattern 720 or the redistribution via 740 of the first redistribution structure 700b may be arranged on the plurality of chip pads 420 of the buried semiconductor chip 400.

In some embodiments, when the buried semiconductor chip 400 includes a through electrode, the first redistribution structure 700b may be electrically connected to the second redistribution structure 700a via the buried semiconductor chip 400.

In some embodiments, the buried semiconductor chip 400 may include a Si bridge electrically connecting at least two semiconductor chips 20 arranged on the package substrate 10d. In some embodiments, the buried semiconductor chip 400 may include a Si capacitor, an inductor, an integrated power device (IPD), etc.

Due to the buried semiconductor chip 400, the length in the horizontal direction D1 and/or the thickness in the vertical direction D2 of the semiconductor package 1000d may decrease.

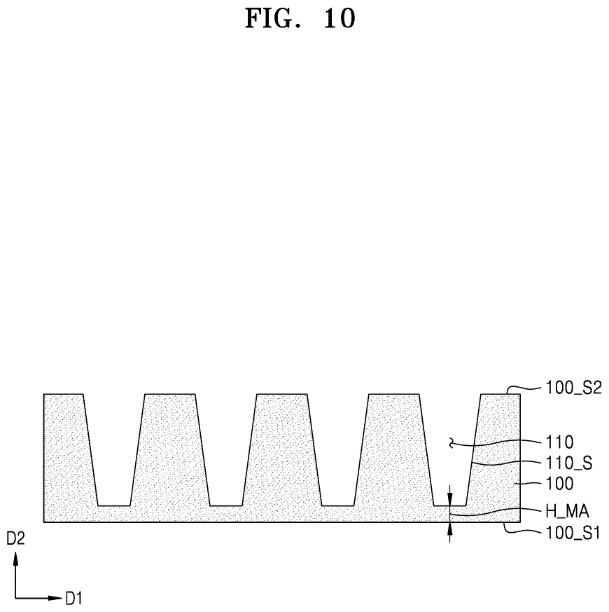

FIGS. 10 through 15 are cross-sectional views illustrating a manufacturing method of a semiconductor package according to a process sequence, according to embodiments.

The manufacturing method of the package substrate 10 may include forming the plurality of through holes 110 in the glass substrate 100, depositing a seed layer P300 on one surface of the glass substrate 100, forming a conductive structure P200, exposing a portion of the conductive structure P200 to the outside by removing a portion of the glass substrate 100 and the seed layer P300, and removing portions of the conductive structure P200 and the seed layer 300. Hereinafter, a semiconductor manufacturing method is described in detail with reference to FIGS. 10 through 15.

Referring to FIG. 10, the plurality of through holes 110 may be formed in the glass substrate 100. The plurality of through holes 110 may extend from the second surface 100_S2 to the first surface 100_S1 of the glass substrate 100 along the vertical direction D2. In this case, the plurality of through holes 110 may not completely penetrate the glass substrate 100. For example, the bottom defining the plurality of through holes 110 may be disposed apart from the first surface 100_S1 of the glass substrate 100 by a certain distance H_MA.

In some embodiments, the plurality of through holes 110 may be formed from the second surface 100_S2 of the glass substrate 100, and accordingly, the horizontal width of the plurality of through holes 110 may decrease toward the first surface 100_S1 of the glass substrate 100. For example, the sidewall 110_S of the glass substrate 100 defining the plurality of through holes 110 may be inclined so that a separation distance between the sidewalls 110_S of the glass substrate 100 defining the plurality of through holes 110 decreases toward the first surface 100_S1 of the glass substrate 100 as the through holes 110 extend along the vertical direction D2.

In some embodiments, the process of forming the plurality of through holes 110 may be performed by using a wet etching or dry etching process, and thus, there may be no crack on the sidewalls 110_S of the glass substrate 100 defining the plurality of through holes 110.

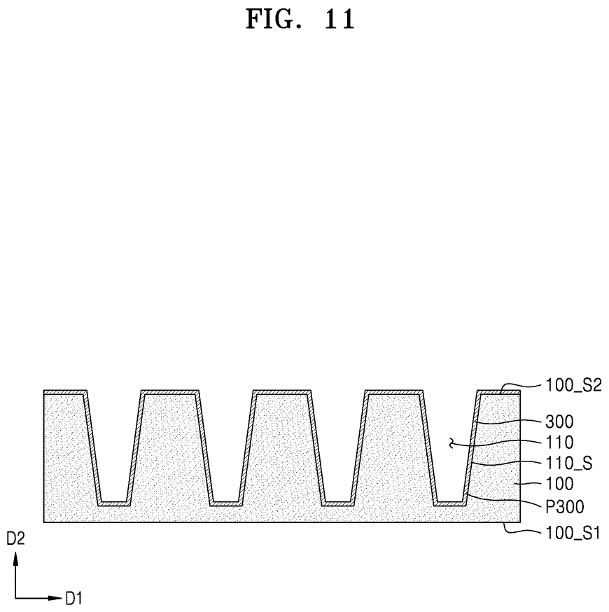

Referring to FIG. 11, the seed layer P300 may be formed on the second surface 100_S2 of the glass substrate 100. In some embodiments, the seed layer P300 may be formed conformal on the second surface 100_S2 of the glass substrate 100 and inside the plurality of through holes 110 (e.g., along the side walls and the bottom of the glass substrate 100 defining the plurality of through holes 110). In some embodiments, the seed layer P300 may be formed by using a deposition process, such as atomic layer deposition (ALD), chemical vapor deposition (CVD), and physical vapor deposition (PVD). Accordingly, the seed layer P300 may be formed to have a constant thickness on the sidewalls 110_S and the bottom of the glass substrate 100 defining the plurality of through holes 110.

In some embodiments, the seed layer P300 may include or may be formed of a metal, such as Cu, Al, W, Ti, Ta, In, Mo, Mn, Co, Sn, Ni, Mg, Re, Be, Ga, and Ru, or an alloy thereof, but is not limited thereto.

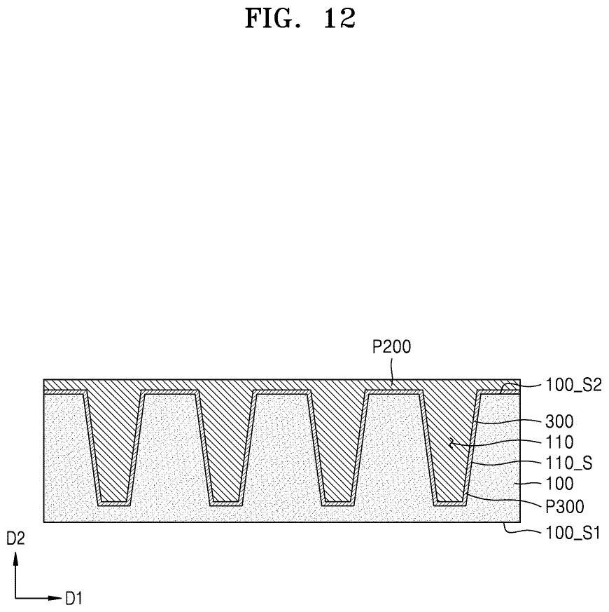

Referring to FIG. 12, the conductive structure P200 may be formed to fill the plurality of through holes 110 and cover the second surface 100_S2 of the glass substrate 100. The conductive structure P200 may be formed by using an electroplating process using the seed layer P300 as a medium.

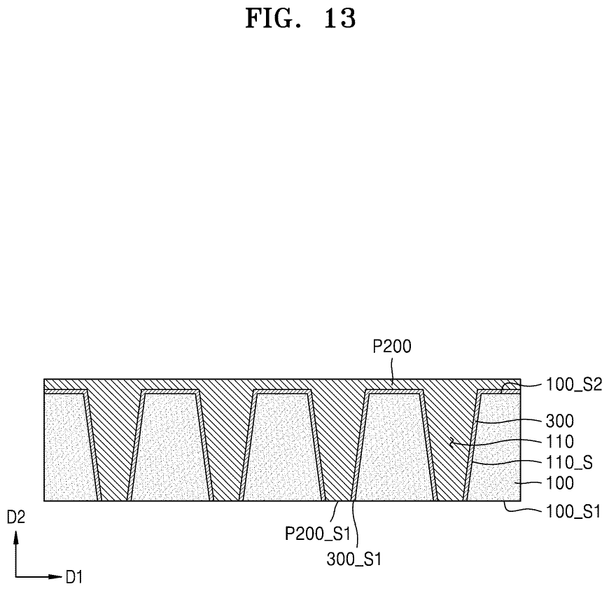

Referring to FIG. 13, by removing portions of the glass substrate 100 and the seed layer P300, a first surface P200_S1 of the conductive structure P200 may be exposed to the outside. When a lower portion of the glass substrate 100 is removed by using an etching process or a grinding process, a portion formed on the bottom of the seed layer P300 defining the plurality of through holes 110 may be removed together. Accordingly, the first surface P200_S1 of the conductive structure P200 covered by the seed layer P300 may be exposed to the outside. In addition, the first surface 300_S1 of the seed layer 300, from which the bottom portion thereof has been removed, may be exposed to the outside. In this case, the first surface 300_S1 of the seed layer 300, from which the bottom portion thereof has been removed, the first surface P200_S1 of the conductive structure P200, and the first surface 100_S1 of the glass substrate 100 may be coplanar with each other.

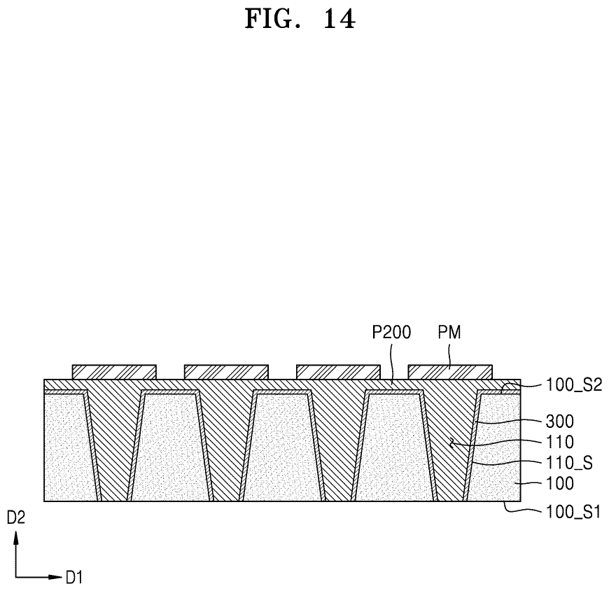

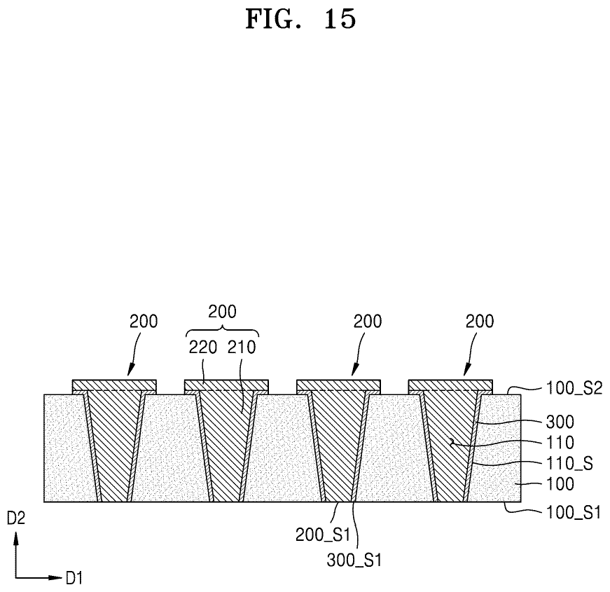

Referring to FIGS. 14 and 15, a plurality of wiring patterns 200 and the seed layer 300 may be formed by removing portions of the conductive structure P200 and the seed layer P300. In some embodiments, a mask PM may be formed on the upper surface of the conductive structure P200, an etching process may be performed thereon, and the conductive structure P200 and the seed layer P300, which are not covered by the mask PM, may be removed.

A portion of the conductive structure P200 may be removed, and the conductive structure P200 may become the plurality of wiring patterns 200 including the through electrode 210 filling the plurality of through holes 110 and the via pad 220 covering a portion of the second surface 100_S2 of the glass substrate 100. In some embodiments, the conductive structure P200 and the seed layer P300 may be removed by using the same mask PM, and thus, the side surface (220S in FIG. 2) of each of the plurality of wiring patterns 200 and the side surface (P_300S in FIG. 2) of the seed layer 300 may be coplanar with each other.

While aspects of the inventive concept have been particularly shown and described with reference to embodiments thereof, it will be understood that various changes in form and details may be made therein without departing from the spirit and scope of the following claims.

What is claimed is:

1. A package substrate comprising:
a glass substrate including a first surface and a second surface opposite thereto, and including a plurality of through holes extending from the second surface to the first surface of the glass substrate;
a plurality of wiring patterns each including a through electrode positioned in the plurality of through holes and a via pad extending from the through electrode to cover a portion of the second surface of the glass substrate; and
a seed layer arranged between the glass substrate and the plurality of wiring patterns, and including a first surface coplanar with the first surface of the glass substrate,
wherein the through electrode of each of the plurality of wiring patterns comprises a first surface coplanar with the first surface of the glass substrate.

2. The package substrate of claim 1,
wherein the glass substrate comprises sidewalls defining the plurality of through holes, and
wherein the seed layer comprises a first portion between the second surface of the glass substrate and the via pad, and a second portion that extends from the first portion to the first surface of the glass substrate along the sidewalls of the glass substrate.

3. The package substrate of claim 2, wherein a side surface of the first portion of the seed layer is coplanar with a side surface of the via pad of each of the plurality of wiring patterns.

4. The package substrate of claim 1, wherein the seed layer extends conformally along a portion of the second surface of the glass substrate and sidewalls of the glass substrate defining each of the plurality of through holes.

5. The package substrate of claim 1, wherein a horizontal width of each of the plurality of through holes of the glass substrate decreases toward the first surface of the glass substrate.

6. The package substrate of claim 1, wherein a horizontal width of the via pad of each of the plurality of wiring patterns is greater than a horizontal width of each of the plurality of through holes.

7. The package substrate of claim 1, further comprising:
a redistribution structure including a plurality of first redistribution vias on the first surface of the glass substrate; and
a plurality of external connection terminals on the via pad of each of the plurality of wiring patterns, and disposed apart from the glass substrate in a vertical direction,
wherein some of the plurality of the first redistribution vias of the redistribution structure contact the first surface of the through electrode of each of the plurality of wiring patterns, and
a redistribution insulating layer of the redistribution structure covers a portion of the first surface of the through electrode and the first surface of the seed layer.

8. The package substrate of claim 1, further comprising:
a redistribution structure on the second surface of the glass substrate; and
a plurality of external connection terminals covering a portion of the first surface of the glass substrate, the first surface of the seed layer, and the first surface of the through electrode of each of the plurality of wiring patterns.

9. The package substrate of claim 1, further comprising:
a first redistribution structure including a plurality of first redistribution vias on the first surface of the glass substrate; and
a second redistribution structure including a plurality of second redistribution vias on the second surface of the glass substrate.

10. The package substrate of claim 9, wherein some of the plurality of first redistribution vias of the first redistribution structure contact the first surface of the through electrode of each of the plurality of wiring patterns.

11. The package substrate of claim 10, wherein a horizontal width of the first redistribution vias in contact with the first surface of the through electrode of each of the plurality of wiring patterns among the plurality of first redistribution vias of the first redistribution structure is less than a horizontal width of the through hole of the glass substrate.

12. The package substrate of claim 10, wherein the redistribution insulating layer of the first redistribution structure covers a portion of the first surface of the through electrode and the first surface of the seed layer.

13. The package substrate of claim 9, wherein some of the plurality of second redistribution vias of the second redistribution structure contact the via pad of each of the plurality of wiring patterns above the through hole.

14. The package substrate of claim 1,
wherein the plurality of wiring patterns are disposed apart from each other in a horizontal direction, and
center vertical axes of two adjacent wiring patterns among the plurality of wiring patterns are disposed apart from each other by about 100 μm to about 200 μm.

15. A semiconductor package comprising:
a package substrate; and
at least one semiconductor chip arranged on the package substrate,
wherein the package substrate comprises:
a glass substrate including a first surface and a second surface opposite thereto, and including a plurality of through holes extending from the second surface to the first surface of the glass substrate;
a plurality of wiring patterns respectively positioned in the plurality of through holes, the plurality of wiring patterns each including a through electrode comprising a first surface coplanar with the first surface of the glass substrate and a via pad extending from the through electrode to cover a portion of the second surface of the glass substrate;
a seed layer arranged between the glass substrate and the plurality of wiring patterns, and including a first surface coplanar with the first surface of the glass substrate; and
a first redistribution structure arranged on at least one surface of the first surface and the second surface of the glass substrate,
wherein the through electrode of each of the plurality of wiring patterns comprises a first surface coplanar with the first surface of the glass substrate.

16. The semiconductor package of claim 15,
wherein the package substrate further comprises a second redistribution structure,
wherein the second redistribution structure is arranged on a surface, on which the first redistribution structure is not arranged, among the first surface and the second surface of the glass substrate, and
wherein a redistribution insulating layer of a redistribution structure arranged on the first surface of the glass substrate among the first redistribution structure and the second redistribution structure covers the first surface of the glass substrate, the first surface of the seed layer, and a portion of the first surface of the through electrode.

17. The semiconductor package of claim 15,
wherein, when the first redistribution structure is arranged on the first surface of the glass substrate, a redistribution via of the first redistribution structure having a horizontal width less than a horizontal width of the through hole contacts each of the plurality of wiring patterns.

18. The semiconductor package of claim 15,
wherein the package substrate comprises a cavity extending from the first surface of the glass substrate to the second surface of the glass substrate, and
further comprises a buried semiconductor chip inside the cavity.

19. The semiconductor package of claim 15,
wherein the at least one semiconductor chip is mounted on the package substrate such that an active surface of the at least one semiconductor chip faces the package substrate, and the at least one semiconductor chip is electrically connected to the plurality of wiring patterns via the first redistribution structure.

20. A semiconductor package comprising:
a package substrate;
at least one semiconductor chip arranged on the package substrate; and
an external connection terminal arranged on the package substrate, and disposed apart from the at least one semiconductor chip with the package substrate therebetween,
wherein the package substrate comprises:
a glass substrate including a first surface and a second surface opposite thereto, and including a plurality of through holes comprising a horizontal width decreasing and extending from the second surface to the first surface of the glass substrate;
a plurality of wiring patterns respectively positioned in the plurality of through holes, the plurality of wiring patterns each including a through electrode comprising a first surface coplanar with the first surface of the glass substrate and a via pad extending from the through electrode to cover a portion of the second surface of the glass substrate;
a seed layer arranged between the glass substrate and the wiring patterns, and including a first surface coplanar with the first surface of the glass substrate;
a first redistribution structure including a plurality of redistribution vias, a redistribution insulating layer, and a plurality of redistribution line patterns, and arranged on the first surface of the glass substrate; and
a second redistribution structure arranged on the second surface of the glass substrate, and including a plurality of redistribution vias, a redistribution insulating layer, and a plurality of redistribution line patterns,
wherein the plurality of redistribution vias of the first redistribution structure have a horizontal width less than a horizontal width of each of the plurality of through holes, and contact the first surface of the through electrode of the plurality of wiring patterns.
